(19) United States
(12) Patent Application Publication
(10) Pub. No.: US 2012/0235267 A1
(43) Pub. Date: Sep. 20, 2012

(54) PHOTODIODE OF THE TYPE AVALANCHE PHOTODIODE

(75) Inventors: Jacob Larsson, Stockholm (SE); Niclas Carlsson, Arsta (SE)

(73) Assignee: SVEDICE AB, Jarfalla (SE)

(21) Appl. No.: 13/497,546

(22) PCT Filed: Sep. 2, 2010
(86) PCT No.: PCT/SE2010/050936

§ 371 Date: May 29, 2012

(30) Foreign Application Priority Data
Sep. 24, 2009 (SE) 0950698-1

(51) Int. Cl. H01L 31/0232

(52) U.S. Cl. 257/432; 257/E31.128

(57) ABSTRACT

A front-illuminated avalanche photodiode (APD) includes an opening (16) for incident light, a number of various semiconductor layers from the opening and downwards including a multiplication layer (7), a field-control layer (8) and an absorption layer (10), where the absorption layer is arranged to absorb photons. Under the absorption layer (10) there is at least one Bragg mirror (14) arranged to reflect photons, that have passed the absorption layer (10) from the opening back to the absorption layer.

The present invention relates to a front-illuminated avalanche photodiode (APD).

An avalanche photodiode (APD) is a semiconductor component that is used in optical fibre networks as a detector or as an optical receiver. The photodiode converts optical signals to electrical signals through photons being absorbed and creating charge carriers in the form of electron-hole pairs. This takes place in a semiconductor layer with a band gap that is less than the energy of the photons. The charge carriers are subsequently accelerated in an electrical field in a second layer, the multiplication layer, in the component to such an energy that further charge carriers are created. These are accelerated onwards in the same way and become multiplied in a process with the nature of an avalanche, from which the name “Avalanche Photodiode” is derived.

The component is illuminated from above and has a round opening of magnitude approximately 30 μm, through which light enters the component. The lower surface of the component is normally welded onto a support. The manufacture of the component takes place, in principle, in one surface layer of a semiconductor substrate. This surface of the substrate and the component is the front surface. The other surface is ground down when the component is complete and forms the back surface.

One important parameter of an APD is how well it absorbs the incident light, where only a fraction of the photons are absorbed. The absorbed photons are converted to an electrical current.

The problem is to achieve an efficient absorption without compromising on other parameters. It is possible to increase the absorption by making the absorption layer thicker, such that the photons travel along a longer distance during which they can be absorbed, but this reduces the bandwidth since the charge carriers require longer time to be transported through what is known as the depletion area of the photodiode. It is also possible to increase the absorption by placing the absorption layer in a resonance cavity, in order to reflect in this way the light forwards and backwards through the absorption layer. This gives efficient absorption, but only for light of a narrow wavelength interval and not for a broader spectrum.

The present invention solves the problem of increasing the absorption in a front-illuminated APD.

The present invention thus relates to a front-illuminated Avalanche Photodiode (APD) comprising an opening for incident light, comprising a number of different semiconductor layers from the opening and downwards comprising a multiplication layer, a field-control layer and an absorption layer, where the absorption layer is arranged to absorb photons and it is characterised in that at least one Bragg mirror is arranged under the absorption layer to reflect photons that have passed the absorption layer from the opening back to the absorption layer.

The invention will be described in more detail below, partly in association with embodiments of the invention shown in the attached drawings, where:

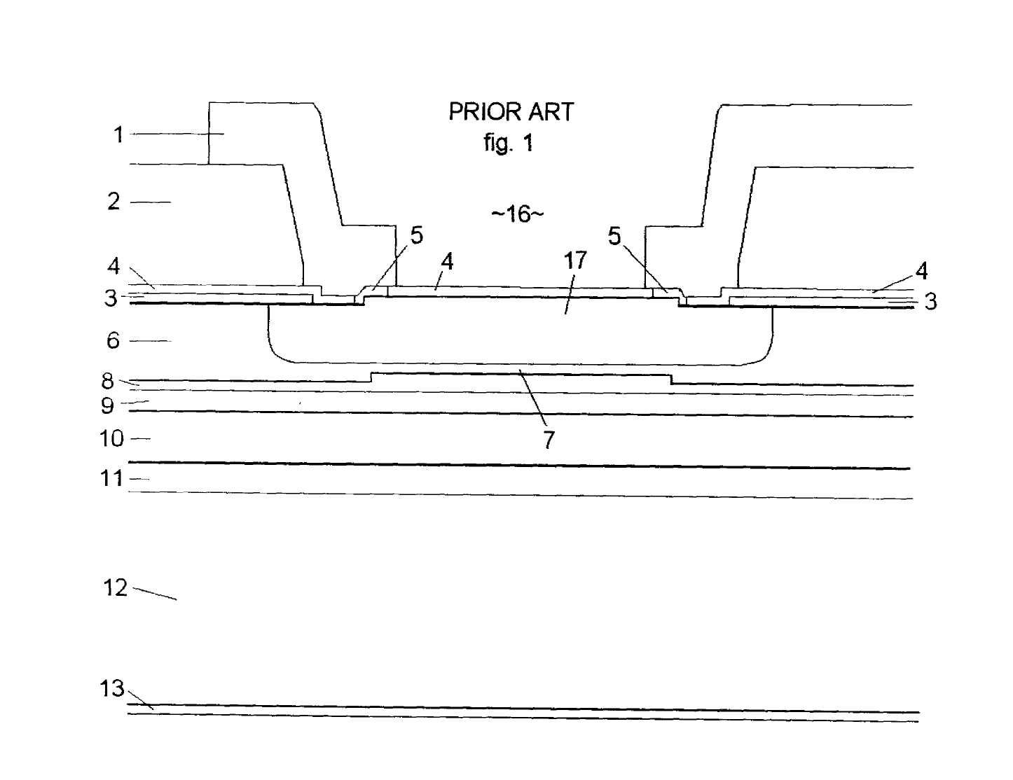

FIG. 1 shows an ADP according to prior art technology,

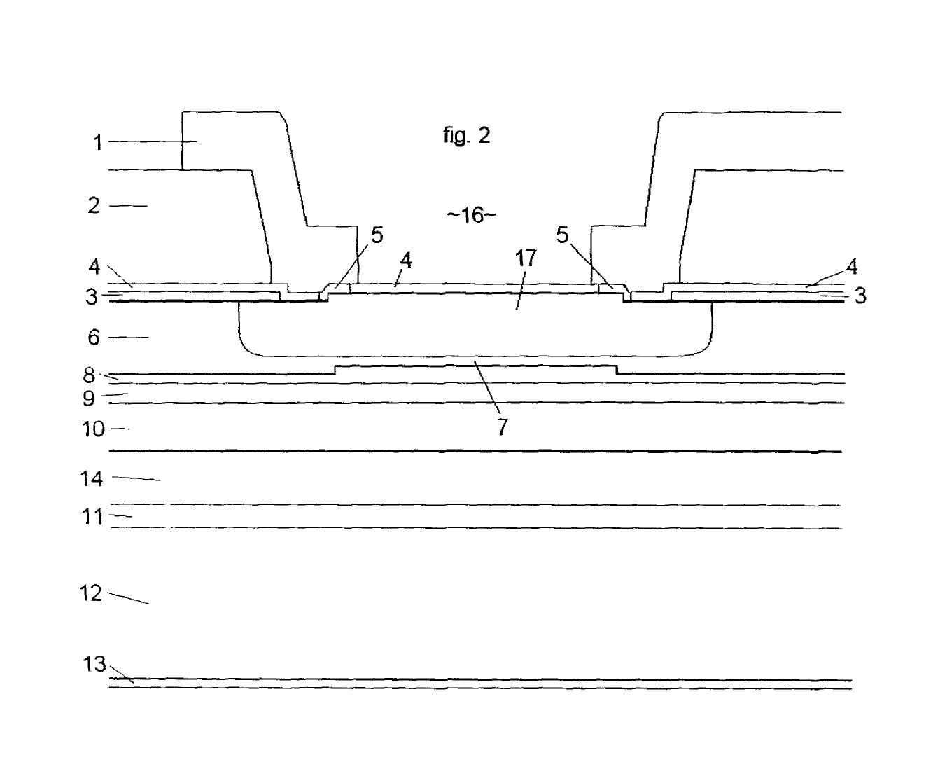

FIG. 2 shows an ADP in which the invention is applied, according to a first embodiment, and

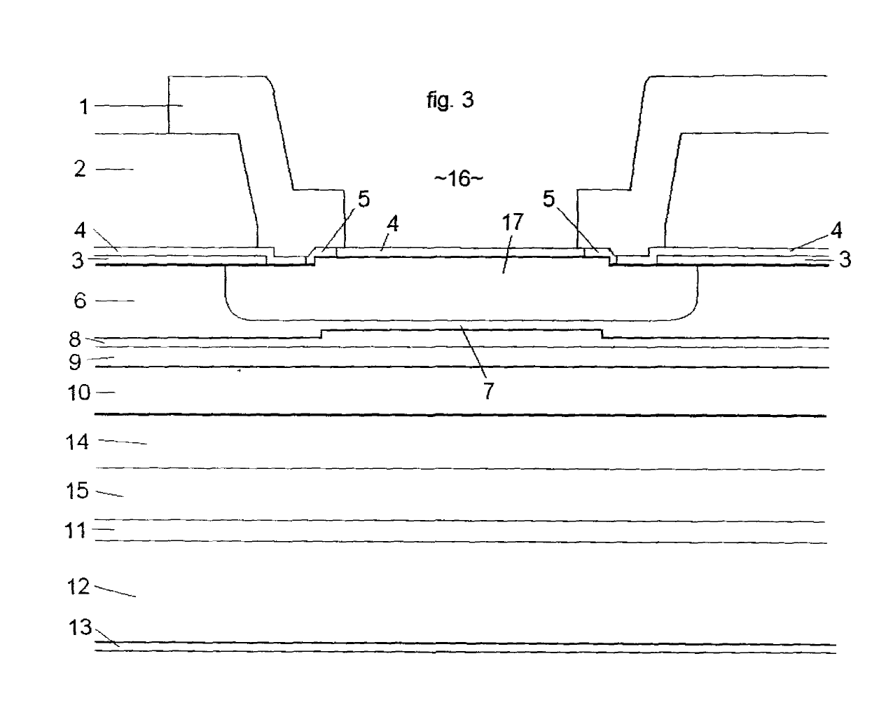

FIG. 3 shows an ADP in which the invention is applied, according to a second embodiment.

FIG. 1 shows a sketch in cross-section of an example of an APD manufactured in the InGaAsP material system. In order to manufacture such an APD, a base structure is first grown on a substrate 12 by MOVPE (Metal Organic Vapour Phase Epitaxy), where the base structure consists of the layers 11, 10, 9, and 8 in FIG. 1, after which an elevation of magnitude approximately 60 nm is etched into the layer 8 using RIE (Reactive Ion Etching). The layer with reference number 11 is a buffer layer of n+-doped InP of thickness approximately 500 nm, the task of which is to be a base for the growth of the continued structure that is as free as possible from defects. The layer 10 is an absorption layer of InGaAs of thickness of approximately 1 μm in which the photons are absorbed, i.e. the absorption layer. The layer 9 is a continuous transition from InGaAs to InP of thickness approximately 100 nm, in which Ga is gradually exchanged for In and As exchanged for P. The task of the layer 9 is to eliminate a discontinuity in the band gap, which forms a barrier for the charge carriers. The layer 8 is a field-control layer of thickness approximately 200 nm, the task of which is to draw the electrical field down into the absorption layer.

A p-doped layer is defined by zinc diffusion through a mask of silicon nitride 3 down into an InP layer of thickness 2.1 μm, with reference number 6, that is grown by a second epitaxy process. The zinc diffusion is subsequently carried out in an epitaxy reactor and extends approximately 1.8 μm down into the InP and defines the p-side of the pn-transition, and at the same time the contact layer, to which the semiconductor material on the p-side has been placed in electrical contact. The doped region has the reference number 17. The layer with reference number 7 is an undoped part of the layer 6 and constitutes the multiplication layer.

The task of the etched elevation in the layer 8 is to reduce the electrical field in the multiplication layer at the edge compared to the central part of the component, in order to avoid edge breakdown, which otherwise occurs there due to the radius of curvature of the p-doped region.

An anti-reflection layer 4 of silicon nitride of approximate thickness 200 nm is subsequently deposited onto the component, in which layer an opening is made and from which an electrical contact 5 is made to a connector 1 by metal vapour and lift-off. The connector 1 consists of Au/Zn/Au from the bottom upwards, with approximate thicknesses 10/30/100 nm. In order to reduce the capacitance contribution from the contact, which connects the chip to a support, a layer 2 of a polymeric electrically insulating material of thickness 5 μm is deposited, on which the connector 1 is placed. The connector 1 is electroplated on a sputtered base of TiW/Au with approximate thicknesses of 50/150 nm, and it is defined by lithography with openings, where the plating is to take place.

The rear surface, i.e is the lower surface of the component, is subsequently ground down with aluminium oxide and it is polished by chlorine-based polishing to a thickness of approximately 120 μm, and it is subsequently coated with a layer 13 of TiW/Au of thicknesses 50/150 nm, which is sputtered onto the said rear surface.

When the component is in its normal operating mode it is under inverse tension, which means that it has a positive potential connected to the n-side, i.e. the rear, of the component, and negative potential connected to the p-side, i.e. the front. The multiplication layer 7, the field-control layer 8, the layer 9 and the absorption layer 10 are in this case depleted. A photon that enters the component and is absorbed in the absorption layer generates an electron-hole pair, which is swept away by the electrical field and generate a photocurrent. The holes are swept away towards the p-contact and reach the multiplication layer, where the field is at its highest in the component. They are accelerated and generate more charge carriers due to their high energy. These are also accelerated and in this way generate further charge carriers in a process that has the nature of an avalanche. An amplification of the photocurrent from the component is obtained in this way.

In order for a photon to be absorbed in the absorption layer, it must have an energy that is higher than the band gap in the layer, otherwise it is simply transported straight through the component without being influenced. The material is in this case transparent for incident light. Since the absorption layer in this embodiment is of InGaAs, it means that the photons must have an energy higher than the band gap in InGaAs, i.e approximately 0.75 eV. This corresponds to light with a wavelength shorter than approximately 1650 nm, and thus covers the wavelengths that are used in commercial fibre optical networks.

That which has been described with reference to FIG. 1 essentially belongs to the prior art technology.

The present invention considerably increases the absorption of photons while at the same time the bandwidth is not negatively affected, i.e. it does not become narrower.

According to the present invention, under the absorption layer 10 there is at least one Bragg mirror 14 arranged to reflect photons that have passed the absorption layer from the opening 16 back to the absorption layer.

According to one preferred embodiment, the Bragg mirror is built up from a periodic structure of alternating InP layers and AlInGaAs layers.

According to another preferred embodiment, the thicknesses of the said InP layers and AlInGaAs layers are adapted to reflect light of a predetermined wavelength.

The Bragg mirror 14 reflects the light that has not been absorbed back into the structure such that it passes the absorption layer 10 one more time. The Bragg mirror 14 is built up from a periodic structure of alternating InP and AlInGaAs layers that are plane and have a constant thickness. The thicknesses of the layers are adapted such that the mirror reflects light in the interval of wavelengths that is desired. The Bragg mirror, for example, can be built up from 10 repetitions of InP and AlInGaAs layers.

The layers of InP and AlInGaAs are grown using MOVPE. InP and related materials are III-V semiconductors and consist of half Group III and half Group V substances, which occupy Group III and Group V sites, respectively, in a crystal. In the case of InP, the In is the only Group III substance and the As is the only Group V substance. In the Bragg mirror 14 of AlInGaAs, the proportions of the Group III substances as a percentage of atoms are: In 53%, Ga 42% and Al 5%, while As is the only Group V substance in the compound. A mirror having 10 repetitions of thickness 121.5 nm for InP and 110 nm for AlInGaAs has theoretically a reflectance maximum at a wavelength of 1551.5 nm and a spectral width of 110 nm defined as the width within which the reflectance is greater than 50%. Theoretical calculations give also a maximal reflectance of approximately 62%. These values are rather estimations than expected exact values, since the calculations depend heavily on, among other factors, the refractive index that is used for the AlInGaAs layers.

The reflectance spectrum of the Bragg mirror is heavily influenced by the periodic length of the layers that build up the mirror, such that longer periods displace the spectrum in the long-wavelength direction and vice versa. The periodic length is the thickness of one pair of the said layers, for example one layer of InP and one layer of AlInGaAs. The variation that is present in the MOVPE process leads to variation also in the spectrum of the mirror, which may result in the mirror no longer covering the complete wavelength interval required.

This problem is solved with a highly preferred embodiment of the invention, through there being at least two Bragg mirrors 14, 15, one lying above the other, and where the Bragg mirrors have different reflectance spectra, and where the reflectance spectra of the two Bragg mirrors are arranged to give together a broader reflectance spectrum.

A design is shown in FIG. 3, in which there are two Bragg mirrors 14, 15, one lying above the other. The two Bragg mirrors have different reflectance spectra, where the reflectance spectra of the two Bragg mirrors are arranged to give together a broader reflectance spectrum.

The two Bragg mirrors 14, 15 have somewhat different period lengths in their structures, which results in them together covering a larger interval with a high reflectance.

According to one preferred embodiment, one of the two Bragg mirrors 14, 15 has a period length that is a certain defined distance shorter than that of a photodiode with only one Bragg mirror, and where the second of the Bragg mirrors 14, 15 has a period length that is the said certain distance longer than that of a photodiode with only one Bragg mirror.

In one embodiment, the Bragg mirrors differ such that the period length of one has been made 2.5% shorter, and the period length of the other 2.5% longer. Instead of the period length of 231.5 nm that is present when only a single Bragg mirror is used, 243 nm and 220.5 nm respectively are used. The Bragg mirror with the shorter period length gives a wavelength interval of 1450-1570 nm, while the Bragg mirror with the longer period length gives a wavelength interval of 1530-1650 nm. The reflectance in this case is approximately 50%.

A number of embodiments and materials have been described above.

The invention can, however, be varied with respect to choice of material and the thicknesses of the component layers for an APD. Thus, the present invention is not limited to any special APD.

The present invention is thus not to be considered to be limited to the embodiments specified above since it can be varied within the scope specified by the attached patent claims.

1-6. (canceled)

7. A front-illuminated avalanche photodiode (APD) comprising an opening (16) for incident light, comprising a number of various semiconductor layers from the opening and downwards comprising a multiplication layer (7), a field-control layer (8) and an absorption layer (10), where the absorption layer is arranged to absorb photons, where at least one Bragg mirror (14) is present under the absorption layer (10) arranged to reflect photons that have passed the absorption layer (10) from the opening back to the absorption layer, characterised in that the Bragg mirror (14) is built up from a periodic structure of alternating InP layers and AlInGaAs layers and in that there are at least two Bragg mirrors (14, 15), one lying above the other, in that the Bragg mirrors have different reflectance spectra, and in that the reflectance spectra of the two Bragg mirrors are arranged to give together a broader reflectance spectrum.

8. A photodiode according to claim 7, characterised in that the thicknesses of the said InP layers and AlInGaAs layers are adapted to reflect light in a predetermined wavelength interval.

9. A photodiode according to claim 8, characterised in that the period length of one of the two Bragg mirrors differs from the other Bragg mirror.

10. A photodiode according to claim 9, characterised in that one of the two Bragg mirrors (14, 15) has a period length that is a certain defined distance shorter than that of a photodiode with only one Bragg mirror, and in that the other Bragg mirror (14, 15) has a period length that is the said certain distance longer than that of a photodiode with only one Bragg mirror.
